(19) United States
(12) Patent Application Publication
(10) Pub. No.: US 2018/0298920 A1
(43) Pub. Date: Oct. 18, 2018

(54) FAN DEVICE

(71) Applicant: Nidec Corporation, Kyoto (JP)

(72) Inventors: Norihisa HINO, Kyoto (JP); Shoki YAMAZAKI, Kyoto (JP); Tadayuki KANATANI, Kyoto (JP); Takaya OKUNO, Kyoto (JP)

(21) Appl. No.: 15/935,199

(22) Filed: Mar. 26, 2018

(30) Foreign Application Priority Data
Apr. 17, 2017 (JP) 2017-081589

(51) Int. Cl. F04D 29/58; H05K 1/14; H05K 1/18; H05K 7/14; F04D 25/16; F04D 17/16

(52) U.S. Cl. CPC F04D 29/5813; H05K 1/144; H05K 1/18; H05K 7/1427; F04D 25/0613; F04D 17/16; H05K 2201/10189; H05K 2201/042; F04D 25/166

(57) ABSTRACT

A fan device includes a fan motor and a board storage unit for storing plural circuit boards. The fan motor includes an impeller rotating around a central axis and a wall surface surrounding the impeller outward in a radial direction. The board storage unit is disposed outward from the wall surface in the radial direction. The circuit boards include first and second circuit boards. As viewed from an opposing direction of the first and second circuit boards, the first circuit board has a first opposing area overlapping the second circuit board and a first non-opposing area which does not overlap the second circuit board, and the second circuit board has a second opposing area overlapping the first circuit board and a second non-opposing area which does not overlap the first circuit board. An electronic component or a lead wire is disposed in each of the first and second non-opposing areas.

### CROSS REFERENCE TO RELATED APPLICATIONS

This application claims the benefit of priority to Japanese Patent Application No. 2017-081589 filed on Apr. 17, 2017. The entire contents of this application are hereby incorporated herein by reference.

### BACKGROUND OF THE INVENTION

### 1. Field of the Invention

The present invention relates to a fan device.

### 2. Description of the Related Art

Japanese Unexamined Patent Application Publication No. H10-117457 discloses a rotating electric motor including a terminal box. The terminal box houses a board at the outer periphery of a frame of the rotating electric motor. Plural terminal blocks to which a power-supply lead wire and other lead wires are connected are mounted on the board. The terminal blocks to which the other lead wires are connected are covered by a second board on which a terminal block to which display and control lead wires are connected is mounted. The second board is fixed onto and supported by the board by using spacers.

### SUMMARY OF THE INVENTION

In the configuration disclosed in the above-described publication, if the board on which the terminal blocks with the other lead wires are mounted is thicker, the distance between the board and the second board is also increased. As a result, the size of the rotating electric motor is increased.

A fan device according to a preferred embodiment of the invention includes a fan motor and a board storage unit for storing a plurality of circuit boards therein. The fan motor includes an impeller and a wall surface. The impeller rotates around a central axis. The wall surface surrounds the impeller outward in a radial direction. The board storage unit is disposed outward from the wall surface in the radial direction. The plurality of circuit boards include first and second circuit boards to be connected to each other such that the first and second circuit boards oppose each other. As viewed from a direction in which the first and second circuit boards oppose each other, the first circuit board has a first opposing area which overlaps the second circuit board and a first non-opposing area which does not overlap the second circuit board, and the second circuit board has a second opposing area which overlaps the first circuit board and a second non-opposing area which does not overlap the first circuit board. An electronic component or a lead wire is disposed in each of the first and second non-opposing areas.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view of a fan device according to a first embodiment of the invention, as viewed obliquely from above in the axial direction.

FIG. 2 is a perspective view of the configuration of a casing according to the first embodiment.

FIG. 3 is a sectional view of the configuration of a fan motor according to the first embodiment.

FIG. 4 is a perspective view of first and second circuit boards included in the fan device according to the first embodiment.

FIG. 5 is a schematic plan view of the first circuit board according to the first embodiment.

FIG. 6 is a schematic plan view of the second circuit board according to the first embodiment.

FIG. 7 is a perspective view for explaining an example of a storing procedure of the first and second circuit boards into a board storage unit.

FIG. 8 illustrates a first modified example of the fan device according to the first embodiment.

FIG. 9 illustrates a second modified example of the fan device according to the first embodiment.

FIG. 10 illustrates a third modified example of the fan device according to the first embodiment.

FIG. 11 is a plan view of a fan device according to a second embodiment, as viewed from above in the axial direction.

FIG. 12 is a perspective view of first and second circuit boards included in the fan device according to the second embodiment.

### DETAILED DESCRIPTION OF THE PREFERRED EMBODIMENTS

Preferred embodiments of the invention will be described below in detail with reference to the accompanying drawings. In this specification, the extending direction of a central axis CA, which is the axis of rotation of impellers 5 and 101 of fan motors FM of each of fan devices 1 and 100, will be called “the axial direction”, a direction perpendicular to the central axis CA will be called “the radial direction”, and a direction along an arc about the central axis CA will be called “the circumferential direction”.

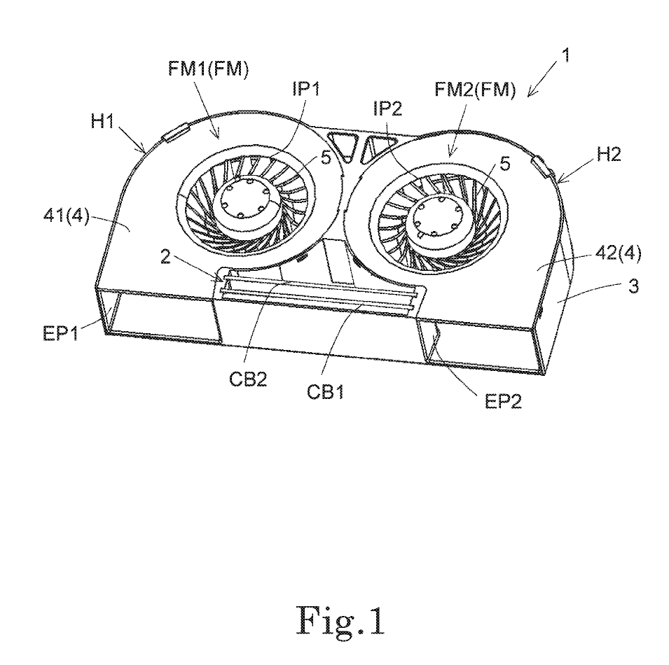

In this specification, the axial direction is set to be the vertical direction. Regarding the axial direction, the direction from a support table 32 supporting a motor unit 10 to the impeller 5 is the upward direction, while the direction from the impeller 5 to the support table 32 is the downward direction. The direction in which the central axes CA of two adjacent fan motors FM are arranged is set to be the horizontal direction. The side on which a first fan motor FM1 in FIG. 1 is positioned is the left side in the horizontal direction, while the side on which a second fan motor FM2 in FIG. 1 is positioned is the right side in the horizontal direction. The direction perpendicular to the vertical direction and the horizontal direction is set to be the front-back direction. The side on which a first circuit board CB1 in FIG. 1 is positioned is the front side, while the side on which a second circuit board CB2 in FIG. 1 is positioned is the back side. However, the definitions of the vertical direction, the horizontal direction, and the front-back direction do not restrict the direction of the fan devices of the embodiments of the invention when they are in use.

FIG. 1 is a perspective view of a fan device 1 according to a first embodiment of the invention, as viewed obliquely from above in the axial direction. As shown in FIG. 1, the fan device 1 includes fan motors FM, a board storage unit 2, a casing 3, and a cover unit 4. The board storage unit 2 stores plural circuit boards CB therein. In the first embodiment, the plural circuit boards CB include a first circuit board CB1 and a second circuit board CB2 to be connected such that they oppose each other. The board storage unit 2 stores the first and second circuit boards CB1 and CB2 such that they oppose each other in the front-back direction. The first and second circuit boards CB1 and CB2 stored in the board storage unit 2 are covered with a resin, which is not shown, so as to be protected from water and dust.

The fan motors FM are centrifugal motors which suck air from suction inlets disposed on one side of the axial direction and which evacuate air from evacuate outlets on the outward side of the radial direction. The fan device 1 includes plural fan motors FM. More specifically, the plural fan motors FM include a first fan motor FM1 and a second fan motor FM2 disposed in the radial direction. In the first embodiment, the first and second fan motors FM1 and FM2 are disposed in the horizontal direction. The first circuit board CB1 includes a control circuit which controls the driving of the first fan motor FM1. The second circuit board CB2 includes a control circuit which controls the driving of the second fan motor FM2.

In the first embodiment, the circuit boards CB including control circuits are stored in the board storage unit 2 disposed outside the fan motors FM. This configuration can provide a larger space for storing the circuit boards CB than the configuration in which circuit boards are disposed within fan motors. This can also lighten restrictions on the size of the surfaces of the circuit boards CB on which electronic components are mounted, thereby making the designing of the circuit boards CB less complicated. Additionally, circuit boards occupy less space within the fan motors FM, which makes it possible to increase the area where air flows. In the first embodiment, the two circuit boards CB1 and CB2 are used for the fan motors FM1 and FM2, respectively, and are disposed such as to oppose each other. This configuration can reduce the area required for the circuit boards CB1 and CB2. That is, in the first embodiment, although plural fan motors FM are disposed, the area required for the board storage unit 2 can be reduced. Hence, the size of the fan device 1 is not increased.

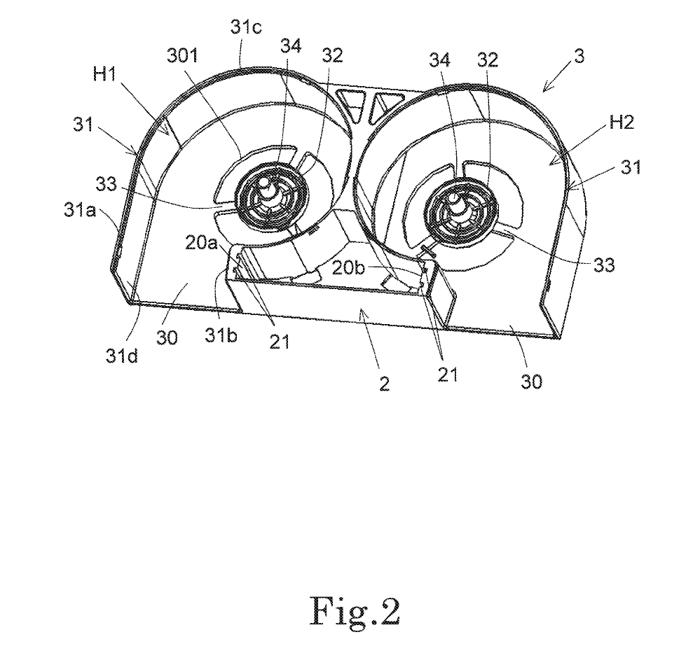

FIG. 2 is a perspective view of the configuration of the casing 3 according to the first embodiment. The casing 3 is made of a resin, for example. The casing 3 includes a first housing H1 and a second housing H2. The first fan motor FM1 is housed in the first housing H1, while the second fan motor FM2 is housed in the second housing H2.

The first housing H1 includes a bottom portion 30 extending in the radial direction and a side wall 31 extending from the bottom portion 30 upward in the axial direction. The side wall 31 has two flat portions 31a and 31b and a curved portion 31c. The flat portions 31a and 31b extend from the front side to the back side and are disposed with a space therebetween in the horizontal direction. The flat portion 31a on the left side extends to the back side longer than the flat portion 31b on the right side. That is, the back end of the flat portion 31a on the left side is positioned farther backward than that of the flat portion 31b on the right side. The curved portion 31c interconnects the back ends of the two flat portions 31a and 31b. The side wall 31 has an opening 31d on the front side.

A circular through-hole 301 passing through the housing H1 in the axial direction is formed on the bottom portion 30. A support table 32 formed in a circular shape as viewed from above in the axial direction is provided at the central portion of the through-hole 301. The support table 32 is linked to the bottom portion 30 via plural interconnecting strips 33 arranged in the circumferential direction. In the first embodiment, three interconnecting strips 33 are provided. The support table 32 includes a tubular support portion 34 extending upward in the axial direction at the central portion of the support table 32. The center of the tubular support portion 34 coincides with the central axis CA of the first fan motor FM1.

The second housing H2 is symmetrical to the first housing H1 with respect to a bisector which divides the casing 3 into two equal parts. That is, the configuration of the second housing H2 is substantially the same as that of the first housing H1, except that the elements forming the first housing H1 and those of the second housing H2 have opposite arrangements in the horizontal direction. That is, the second housing H2 also includes a bottom portion 30, a side wall 31, a support table 32, interconnecting strips 33, and a tubular support portion 34. Details of these elements are similar to those of the first housing H1, and an explanation thereof will thus be omitted.

The board storage unit 2 is provided in the casing 3. The board storage unit 2 is provided on the front side of the casing 3 and at the central portion of the casing 3 in the horizontal direction. The shape of the board storage unit 2 is similar to a box with a closed bottom. The bottom portions 30 of the first and second housings H1 and H2 serve as the bottom portion of the board storage unit 2. The board storage unit 2 is disposed between the first and second housings H1 and H2. Part of the side wall of the board storage unit 2 is constituted by part of the side wall 31 of the first housing H1 and part of the side wall 31 of the second housing H2.

The board storage unit 2 is opened in one direction. The first and second circuit boards CB1 and CB2 are disposed in parallel with one direction. In the first embodiment, this direction is the vertical direction, and more specifically, the board storage unit 2 is opened in the upward direction. The first and second circuit boards CB1 and CB2 are stored in the board storage unit 2 such that the board surfaces are parallel with the vertical direction and the horizontal direction. In other words, the first and second circuit boards CB1 and CB2 are stored in the board storage unit 2 in directions perpendicular to the front-back direction.

The board storage unit 2 has at least one groove 21 depressed outward from an inner surface 20 and extending in one direction. In the first embodiment, two grooves 21 are formed on each of inner surfaces 20a and 20b of the board storage unit 2. The inner surfaces 20a and 20b oppose each other in the horizontal direction. The two grooves 21 formed on the inner surface 20a on the left side are depressed to the left side from the inner surface 20a and extend in the vertical direction. The two grooves 21 formed on the inner surface 20b on the right side are depressed to the right side from the inner surface 20b in the vertical direction. The two grooves 21 formed in the inner surface 20a are arranged in the front-back direction, while the two grooves 21 formed in the inner surface 20b are arranged in the front-back direction. The two grooves 21 in the inner surface 20a and those in the inner surface 20b oppose each other in the horizontal direction.

The inner surfaces of the grooves 21 contact at least one of the board surfaces of each of the first and second circuit boards CB1 and CB2. In the first embodiment, the front and back surfaces of each of the first and second circuit boards CB1 and CB2 are the board surfaces. In the first embodiment, the inner surfaces of the grooves 21 formed on the front side of the inner surface 20a and on the front side of the inner surface 20b contact at least one of the front and back surfaces of the first circuit board CB1. The inner surfaces of the grooves 21 formed on the back side of the inner surface 20a and on the back side of the inner surface 20b contact at least one of the front and back surfaces of the second circuit board CB2. In the first embodiment, the first and second circuit boards CB1 and CB2 are disposed in the board storage unit 2 while being positioned by using the two grooves 21 formed on the left side and those on the right side. This facilitates the storage operation of the first and second circuit boards CB1 and CB2 in the board storage unit 2.

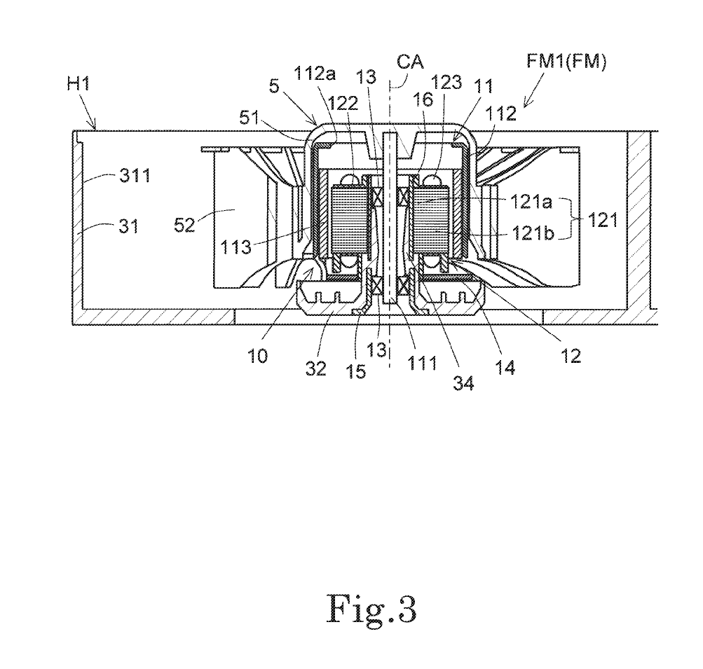

FIG. 3 is a view illustrating the configuration of the fan motor FM according to the first embodiment. More specifically, FIG. 3 is a sectional view of the first fan motor FM1. The configuration of the first fan motor FM1 is similar to that of the second fan motor FM2. The configuration of the fan motor FM will be described by taking the first fan motor FM1 as an example.

As shown in FIG. 3, the first fan motor FM1 includes an impeller 5, a wall surface 311, and a motor unit 10. The impeller 5 is disposed outward from the motor unit 10. The impeller 5 is rotated around the central axis CA by the driving of the motor unit 10. The impeller 5 includes a cup portion 51 and plural blades 52. The cup portion 51 is opened in the downward direction. The plural blades 52 are arranged at equal spaces in the circumferential direction on the outer peripheral surface of the cup portion 51. A stream is generated by the rotation of the impeller 5.

The wall surface 311 surrounds the impeller 5 outward in the radial direction. In the first embodiment, the wall surface 311 corresponds to the inner peripheral surface of the side wall 31 of the first housing H1. The distance from the central axis CA to the wall surface 311 is not uniform, and varies in accordance with the circumferential position of the wall surface 311. Because of the provision of the opening 31d in the side wall 31, the wall surface 311 does not cover part of the impeller 5 outward in the radial direction. The board storage unit 2 is located outward from the wall surface 311 in the radial direction.

The motor unit 10 includes a rotor 11, a stator 12, bearings 13, and an internal circuit board 14. The motor unit 10 is supported by the support table 32.

The rotor 11 includes a shaft 111, a rotor holder 112, and a magnet 113. The shaft 111 extends along the central axis CA. The shaft 111 is a cylindrical member made of a metal, for example. The impeller 5 is fixed onto the upper portion of the shaft 111. The rotor holder 112 is formed in a cup-like shape opening downward. The rotor holder 112 is constituted by a magnetic material made of carbon steel, for example. A rotor hole 112a passing through the rotor holder 112 in the axial direction is formed at the central portion of the top surface of the rotor holder 112. The shaft 111 is inserted into the rotor hole 112a. The cup portion 51 of the impeller 5 is disposed outward from the rotor holder 112 and is fixed to the rotor holder 112. The impeller 5 is fixed to the rotor holder 112 by bonding, pressing, or insert-molding, for example. In accordance with the rotation of the rotor holder 112, the impeller 5 and the shaft 111 are rotated.

The magnet 113 is disposed on the inner peripheral surface of the rotor holder 112. In the first embodiment, the magnet 113 is a single ring-like magnet 113. On the surface of the magnet 113 inward in the radial direction, N poles and S poles are alternately magnetized in the circumferential direction. Instead of the single ring-like magnet 13, plural magnets may be disposed on the inner peripheral surface of the rotor holder 112.

The stator 12 includes a stator core 121, an insulator 122, and plural coils 123. The stator core 121 is constituted by laminated steel sheets formed by overlaying electromagnetic steel sheets on each other in the axial direction. The stator core 121 is located inward from the magnet 113 in the radial direction. The stator core 121 has a ring-like core back 121a and plural teeth 121b extending outward from the core back 121a in the radial direction. The coils 123 are each formed by winding a conducting wire around a corresponding tooth 121b with the insulator 122 interposed therebetween.

The bearings 13 support the rotor 11 so that the rotor 11 is rotatable with respect to the stator 12. More specifically, the bearings 13 are constituted by an upper bearing 13 and a lower bearing 13 disposed on the upper and lower portions of the motor unit 10. The upper and lower bearings 13 are fixed to the outer periphery of the shaft 111. In the first embodiment, the bearings 13 are ball bearings. However, the bearings 13 may be another type of bearing, such as sleeve bearings.

The lower bearing 13 is disposed inward from a tubular first bush 15 in the radial direction and is supported by the first bush 15. The first bush 15 is fixed to the central portion of the support table 32. The upper bearing 13 is disposed inward from a tubular second bush 16 in the radial direction and is supported by the second bush 16. The second bush 16 is fixed to the tubular support portion 34. The stator core 121 is disposed outward from the second bush 16 in the radial direction and is fixed to the second bush 16.

The internal circuit board 14 is disposed below the stator 12 in the axial direction. The internal circuit board 14 is electrically connected to the plural coils 123. The internal circuit board 14 is also electrically connected to a circuit board CB disposed outside the motor unit 10. In the first embodiment, the internal circuit board 14 is electrically connected to the first circuit board CB1. A Hall integrated circuit (IC) may be mounted on the internal circuit board 14 to detect the speed of the rotor 11. However, the provision of a Hall IC is not essential. If a Hall IC is not mounted on the internal circuit board 14, the speed of the rotor 11 may be detected by reading a current flowing through the conducting wires or a voltage across the conducting wires.

As shown in FIG. 1, the cover unit 4 is attached to the top part of the casing 3. The cover unit 4 includes a first cover 41 attached to the top part of the first housing H1 and a second cover 42 attached to the top part of the second housing H2. The first cover 41 has a circular first suction inlet IP1 passing through the cover unit 4 in the vertical direction. The second cover 42 has a circular second suction inlet IP2 passing through the cover unit 4 in the vertical direction. The centers of the first and second suction inlets IP1 and IP2 coincide with the central axis CA of the fan motors FM1 and FM2 housed in the first and second housings H1 and H2. The first and second covers 41 and 42 may be attached to the casing 3 by using at least one of adhesive, screws, and snap-fitting. The first and second covers 41 and 42 may be formed into a single cover 4.

By attaching the first cover 41 to the first housing H1, a first evaluate outlet EP1 of the first fan motor FM1 is formed by the opening 31d. By attaching the second cover 42 to the second housing H2, a second evaluate outlet EP2 of the second fan motor FM2 is formed by the opening 31d. In the first embodiment, the first and second evaluate outlets EP1 and EP2 are arranged in the horizontal direction. The board storage unit 2 is disposed between the first and second evaluate outlets EP1 and EP2. In the first embodiment, the space formed between the first and second fan motors FM1 and FM2 can effectively be utilized as the board storage unit 2, thereby reducing the size of the fan device 1.

In the fan device 1 configured as described above, power is supplied from the first circuit board CB1 to the coils 123 of the first fan motor FM1, while power is supplied from the second circuit board CB2 to the coils 123 of the second fan motor FM2. Upon receiving power supply, magnetic flux is generated in the teeth 121b of the first and second fan motors FM1 and FM2. Due to the action of magnetic flux between the teeth 121b and the magnet 113, torque is generated in the circumferential direction so as to rotate the rotor 11 around the central axis CA. Then, in accordance with the rotation of the rotor 11, the impeller 5 is also rotated. In the first fan motor FM1, rotating of the impeller 5 causes air to be sucked from the first suction inlet IP1 and to be evaluated from the first evacuate outlet EP1. In the second fan motor FM2, rotating of the impeller 5 causes air to be sucked from the second suction inlet IP2 and to be evaluated from the second evacuate outlet EP2. By interrupting power supply to the coils 123, the impeller 5 stops rotating, and the operation of the first and second fan motors FM1 and FM2 is finished.

In the first embodiment, the blades 52 of the first fan motor FM1 and those of the second fan motor FM2 are arranged in opposite directions. The first and second fan motors FM1 and FM2 accordingly rotate in opposite directions. In the first embodiment, the first fan motor FM1 rotates counterclockwise, while the second fan motor FM2 rotates clockwise, as viewed from above in the axial direction.

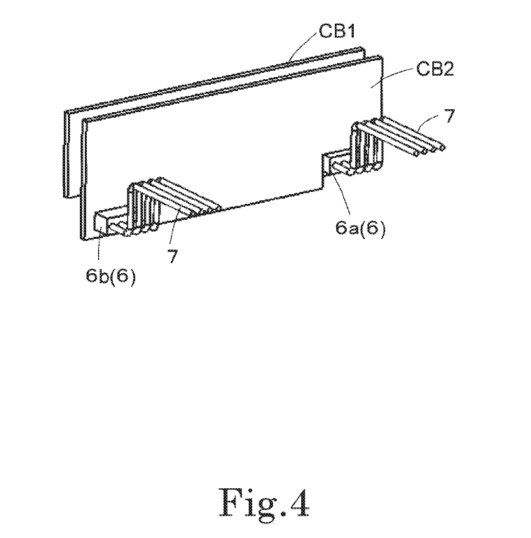

FIG. 4 is a perspective view of the first and second circuit boards CB1 and CB2 included in the fan device 1 according to the first embodiment. More specifically, FIG. 4 is a perspective view of the first and second circuit boards CB1 and CB2 as viewed from obliquely upward from the back side. The first and second circuit boards CB1 and CB2 are disposed with a predetermined distance therebetween to oppose each other in the front-back direction. The first and second circuit boards CB1 and CB2 are electrically connected to each other via a conductive interconnecting pin, which is not shown, for example. For example, one end of the interconnecting pin is fixed to the first circuit board CB1 by soldering, and the other end of the interconnecting pin is fixed to the second circuit board CB2 by soldering. The interconnecting pin preferably has an adjusting member for adjusting the distance between the first and second circuit boards CB1 and CB2 in the front-back direction.

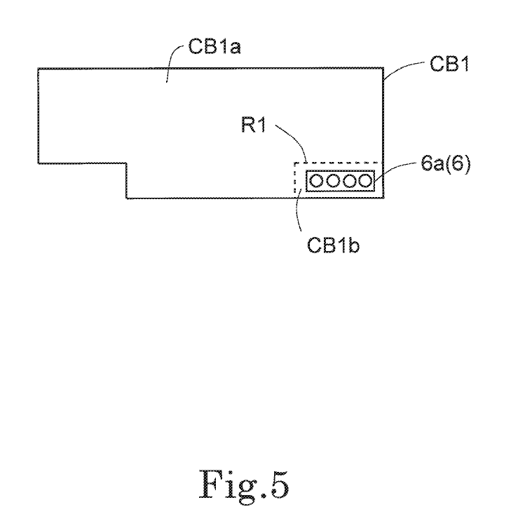

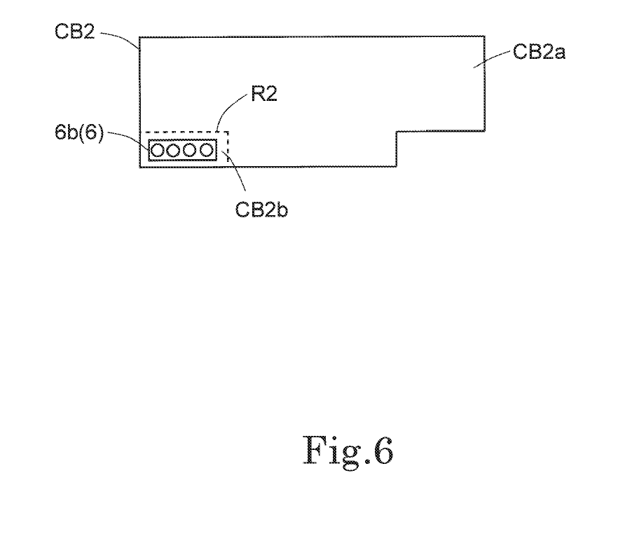

FIG. 5 is a schematic plan view of the first circuit board CB1 according to the first embodiment. FIG. 6 is a schematic plan view of the second circuit board CB2 according to the first embodiment. FIGS. 5 and 6 are plan views of the first and second circuit boards CB1 and CB2 as viewed from backward. In the first embodiment, the opposing direction of the first and second circuit boards CB1 and CB2 is the front-back direction.

As shown in FIG. 5, the first circuit board CB1 has a first opposing area CB1a and a first non-opposing area CB1b. As viewed from the front-back direction, the first opposing area CB1a overlaps the second circuit board CB2, and the first non-opposing area CB1b does not overlap the second circuit board CB2.

As shown in FIG. 6, the second circuit board CB2 has a second opposing area CB2a and a second non-opposing area CB2b. As viewed from the front-back direction, the second opposing area CB2a overlaps the first circuit board CB1, and the second non-opposing area CB2b does not overlap the first circuit board CB1.

In the first embodiment, the first and second circuit boards CB1 and CB2 are congruent with each other. More specifically, in both of the first and second circuit boards CB1 and CB2, one of the two bottom corners is cut out from a rectangular circuit board. The shape of the cutout portion is also rectangular. When the first and second circuit boards CB1 and CB2 are connected to each other, the relationship between the shapes of the circuit boards CB1 and CB2 can be expressed in the following manner. If the first circuit board CB1 is flipped in the horizontal direction, the shape of the first circuit board CB1 coincides with that of the second circuit board CB2. The two top corners of the first circuit board CB1 coincide with those of the second circuit board CB2, as viewed from the front-back direction. In contrast, the rectangular first non-opposing area CB1b on the bottom corner of the first circuit board CB1 does not overlap the second circuit board CB2, while the rectangular second non-opposing area CB2b on the bottom corner of the second circuit board CB2 does not overlap the first circuit board CB1. The position of the first non-opposing area CB1b in the first circuit board CB1 and that of the second non-opposing area CB2b in the second circuit board CB2 are symmetrical to each other. The area other than the first non-opposing area CB1b of the first circuit board CB1 is the first opposing area CB1a, while the area other than the second non-opposing area CB2b of the second circuit board CB2 is the second opposing area CB2a.

In the first embodiment, by using only one board, the first and second circuit boards CB1 and CB2 can be manufactured at the same time, thereby enhancing the manufacturing efficiency.

In the first embodiment, the first and second non-opposing areas CB1b and CB2b are formed by cutting out the bottom corners of the first and second circuit boards CB1 and CB2. Alternatively, non-opposing areas may be formed by providing through-holes in the first and second circuit boards CB1 and CB2. For example, the first and second circuit boards CB1 and CB2 may have been formed in different sizes so as to form non-overlapping areas.

Electronic components or lead wires may be disposed in the first and second non-opposing areas CB1b and CB2b. As shown in FIGS. 5 and 6, in the first embodiment, electronic components 6 are disposed in the first and second non-opposing areas CB1b and CB2b. In the first embodiment, the electronic components 6 are disposed in portions of the first and second circuit boards CB1 and CB2 which do not overlap the other circuit boards CB2 and CB1. It is thus possible to bring the two circuit boards CB1 and CB2 close to each other without letting the electronic components 6 get in the way, thereby reducing the size of the fan device 1. The electronic components 6 may be connectors or busbars, though they are not restricted to these components.

More specifically, a first connector 6a is disposed in the first non-opposing area CB1b as the electronic component 6, and a second connector 6b is disposed in the second non-opposing area CB2b as the electronic component 6. The first connector 6a is disposed on the side of the first circuit board CB1 which opposes the second circuit board CB2. In the first embodiment, the first connector 6a is disposed on the back surface of the first circuit board CB1. The first connector 6a is fixed to the first circuit board CB1 by performing soldering on the front surface of the first circuit board CB1. The second connector 6b is disposed on the side of the second circuit board CB2 which does not oppose the first circuit board CB1. In the first embodiment, the second connector 6b is disposed on the back surface of the second circuit board CB2. The second connector 6b is fixed to the second circuit board CB2 by performing soldering on the front surface of the second circuit board CB2.

In the first embodiment, after the first and second circuit boards CB1 and CB2 are connected to each other, positioning of the first and second connectors 6a and 6b provided at the ends of lead wires 7 on the first and second circuit boards CB1 and CB2 can be performed from the same side. Then, fixing of the first and second connectors 6a and 6b to the circuit boards CB1 and CB2 by using soldering can be performed on the side opposite the side on which positioning of the first and second connectors 6a and 6b is performed. In the first embodiment, the mounting operation of the first and second connectors 6a and 6b with the lead wires 7 on the first and second circuit boards CB1 and CB2 is simple. Hence, the first and second circuit boards CB1 and CB2 can be connected to each other before the first and second connectors 6a and 6b are mounted on the circuit boards CB1 and CB2, thereby enhancing the efficiency of the operation.

In the first embodiment, the lead wires 7 are fixed to the first and second circuit boards CB1 and CB2 via the use of the connectors 6. However, the lead wires 7 may directly be soldered to the first and second circuit boards CB1 and CB2. In this case, the lead wires 7 are fixed to the first and second non-opposing areas CB1b and CB2b, so that they can extend from the circuit boards CB1 and CB2 without being interrupted by the other circuit boards CB2 and CB1. Instead of using soldering to fix the connectors 6 with the lead wires 7 to the circuit boards CB1 and CB2, connectors fixed to the circuit boards CB1 and CB2 in advance may be used to receive the connectors 6.

A first boundary R1 is defined between the first opposing area CB1a and the first non-opposing area CB1b. A second boundary R2 is defined between the second opposing area CB2a and the second non-opposing area CB2b. As viewed from the front-back direction, at least one of the first boundary R1 of the first circuit board CB1 and the second boundary R2 of the second circuit board CB2 preferably opposes part of the periphery of the other circuit board CB2 or CB1. With this configuration, when mounting the electronic components 6 or the lead wires 7 on the first and second circuit boards CB1 and CB2, a tool, such as a soldering iron, can easily be brought close to the mounting portions of the circuit boards CB1 and CB2, thereby enhancing the efficiency of the mounting operation. This configuration is achieved by forming a cutout in at least one of the opposing circuit boards CB. If holes are formed in the opposing circuit boards CB, this configuration is not achieved. In the first embodiment, the first boundary R1 opposes part of the periphery of the second circuit board CB2, while the second boundary R2 opposes part of the periphery of the first circuit board CB1. More specifically, the first and second boundaries R1 and R2 oppose the sides of the first and second circuit boards CB1 and CB2 formed by the cutouts.

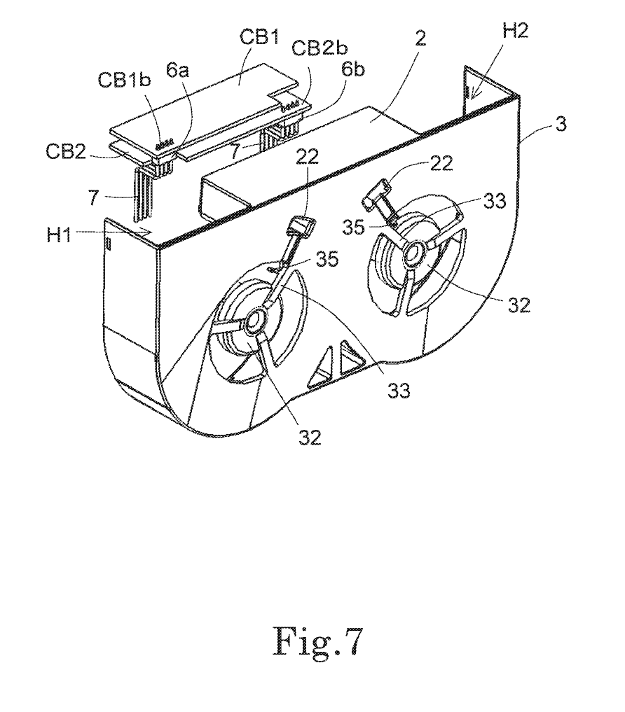

FIG. 7 is a perspective view for explaining an example of the storing procedure of the first and second circuit boards CB1 and CB2 into the board storage unit 2. The first and second circuit boards CB1 and CB2 are connected to each other with a predetermined distance therebetween so as to oppose each other. The first connector 6a with the lead wire 7 is disposed in the first non-opposing area CB1b from the back side. The first circuit board CB1 is located in front of the second circuit board CB2. However, the first non-opposing area CB1b does not overlap the second circuit board CB2 in the front-back direction. Accordingly, the first connector 6a can be disposed in the first non-opposing area CB1b from the back side. The second connector 6b with the lead wire 7 is disposed in the second non-opposing area CB2b from the back side.

In the first embodiment, the ends of the lead wires 7 opposite the ends at the connectors 6a and 6b are soldered to the internal circuit boards 14 of the first and second fan motors FM1 and FM2. The connectors 6a and 6b pass through holes 22 formed on the bottom of the board storage unit 2 and extend toward the board storage unit 2. The lead wires 7 are retained by hooks 35 provided in the interconnecting strips 33 on the way back to the board storage unit 2 from the motor unit 10. Connecting of the lead wires 7 to the internal circuit boards 14 may be performed after finishing the mounting operation of the connectors 6a and 6b on the first and second circuit boards CB1 and CB2.

Soldering of the first connector 6a to the first circuit board CB1 is conducted on the front side of the first non-opposing area CB1b so that the first connector 6a can be fixed to the first circuit board CB1. Soldering of the second connector 6b to the second circuit board CB2 is conducted on the front side of the second non-opposing area CB2b so that the second connector 6b can be fixed to the second circuit board CB2. The second circuit board CB2 is disposed at the back of the first circuit board CB1. However, the second non-opposing area CB2b does not overlap the first circuit board CB1 in the front-back direction. Accordingly, the soldering portion of the second circuit board CB2 for the second connector 6b is exposed without being interrupted by the first circuit board CB1, thereby facilitating the soldering operation.

The first and second circuit boards CB1 and CB2 having the connectors 6a and 6b with the lead wires 7 mounted thereon are stored in the board storage unit 2 while being moved along the grooves 21. Then, a silicone resin, for example, is filled into the board storage unit 2 to cover the first and second circuit boards CB1 and CB2. In the first embodiment, after the circuit boards CB1 and CB2 are connected to each other, mounting of the first and second connectors 6a and 6b with the lead wires 7 on the circuit boards CB1 and CB2 can be performed, thereby enhancing the efficiency of the operation.

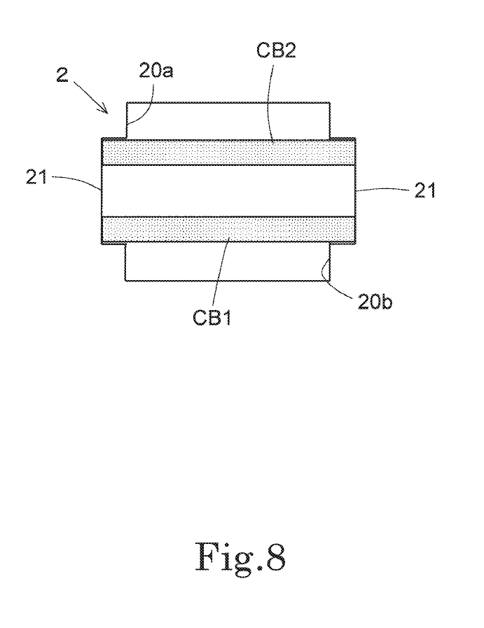

FIG. 8 illustrates a first modified example of the fan device 1 according to the first embodiment. In the first modified example, a groove 21 is formed on each of the inner surfaces 20a and 20b of the board storage unit 2. The groove 21 formed on the inner surface 20a on the left side is depressed to the left side from the inner surface 20a and extends in the vertical direction. The groove 21 formed on the inner surface 20b on the right side is depressed to the right side from the inner surface 20b and extends in the vertical direction. The groove 21 on the inner surface 20a and the groove 21 on the inner surface 20b oppose each other in the horizontal direction.

In the first modified example, the inner surfaces of the grooves 21 formed on the inner surfaces 20a and 20b contact the front surface of the first circuit board CB1 and the back surface of the second circuit board CB2. In the first modified example, when storing the first and second circuit boards CB1 and CB2 in the board storage unit 2, positioning of the circuit boards CB1 and CB2 can be conducted by using the grooves 21. Only one of the front and back surfaces of each of the first and second circuit boards CB1 and CB2 contacts the inner surfaces of the grooves 21. The other surfaces of the first and second circuit boards CB1 and CB2 do not contact the inner surfaces of the grooves 21. This configuration can increase the area where electronic components are mounted.

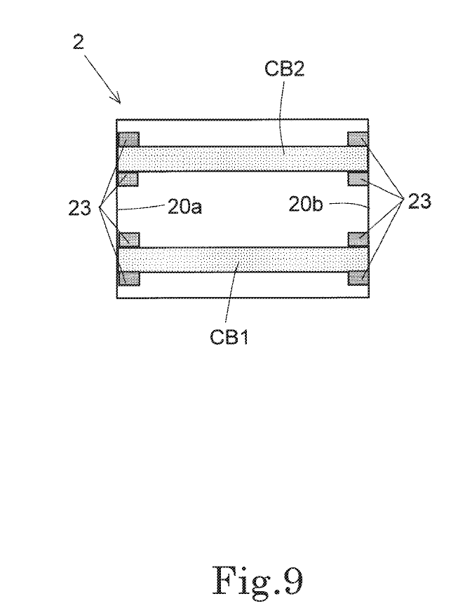

FIG. 9 illustrates a second modified example of the fan device 1 according to the first embodiment. In the second modified example, the board storage unit 2 is opened in one direction. The first and second circuit boards CB1 and CB2 are disposed in parallel with one direction. In the second modified example, this direction is the vertical direction, and more specifically, the board storage unit 2 is opened in the upward direction. The first and second circuit boards CB1 and CB2 are stored in the board storage unit 2 such that the board surfaces are parallel with the vertical direction and the horizontal direction.

An inner surface 20 of the board storage unit 2 has at least two ribs 23 extending in one direction. The first circuit board CB1 or the second circuit board CB2 is disposed between two ribs 23. In the second modified example, four ribs 23 are provided on each of the horizontally opposing inner surfaces 20a and 20b of the board storage unit 2. The four ribs 23 formed on the inner surface 20a on the left side protrude to the right side from the inner surface 20a and extend in the vertical direction. The four ribs 23 formed on the inner surface 20b on the right side protrude to the left side from the inner surface 20b and extend in the vertical direction. Among the four ribs 23 arranged in the front-back direction on each of the inner surfaces 20a and 20b, the two ribs 23 on the front side are ribs for positioning the first circuit board CB1, while the two ribs 23 on the back side are ribs for positioning the second circuit board CB2.

Each of the left and right end portions of the first circuit board CB1 is disposed between the two ribs 23 for the first circuit board CB1. At least one of the front and back surfaces of the first circuit board CB1 preferably contacts the ribs 23 for the first circuit board CB1. Each of the left and right end portions of the second circuit board CB2 is disposed between the two ribs 23 for the second circuit board CB2. At least one of the front and back surfaces of the second circuit board CB2 preferably contacts the ribs 23 for the second circuit board CB2. In the second modified example, each of the left and right end portions of each of the first and second circuit boards CB1 and CB2 is sandwiched between two ribs 23, so that the circuit boards CB1 and CB2 can be stored in the board storage unit 2 while being positioned by the ribs 23. This facilitates the storage operation of the two circuit boards CB1 and CB2 into the board storage unit 2.

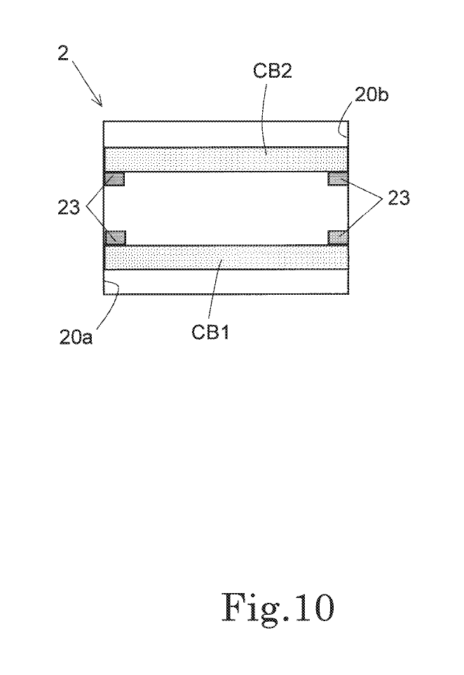

FIG. 10 illustrates a third modified example of the fan device 1 according to the first embodiment. In the third modified example, the board storage unit 2 is opened in one direction. The first and second circuit boards CB1 and CB2 are disposed in parallel with one direction. In the third modified example, this direction is the vertical direction, and more specifically, the board storage unit 2 is opened in the upward direction. The first and second circuit boards CB1 and CB2 are stored in the board storage unit 2 such that the board surfaces are parallel with the vertical direction and the horizontal direction.

An inner surface 20 of the board storage unit 2 has at least one rib 23 extending in one direction. One of the front and back surfaces of the first circuit board CB1 or the second circuit board CB2 contacts the rib 23. In the third modified example, two ribs 23 are provided on each of the horizontally opposing inner surfaces 20a and 20b of the board storage unit 2. The two ribs 23 formed on the inner surface 20a on the left side protrude to the right side from the inner surface 20a and extend in the vertical direction. The two ribs 23 formed on the inner surface 20b on the right side protrude to the left side from the inner surface 20b and extend in the vertical direction. The two ribs 23 provided on each of the inner surfaces 20a and 20b may be linked with each other in the front-back direction to form a single rib.

The left and right end portions of the back surface of the first circuit board CB1 contact the ribs 23. The left and right end portions of the front surface of the second circuit board CB2 contact the ribs 23. In the third modified example, when storing the first and second circuit boards CB1 and CB2 in the board storage unit 2, positioning of the circuit boards CB1 and CB2 can be conducted by using the ribs 23. Only one of the front and back surfaces of each of the first and second circuit boards CB1 and CB2 contacts the ribs 23. The other surfaces of the first and second circuit boards CB1 and CB2 do not contact the ribs 23. This can increase the area where electronic components are mounted. Both of the first and second circuit boards CB1 and CB2 may contact the ribs 23 on the front surfaces, or both of the first and second circuit boards CB1 and CB2 may contact the ribs 23 on the back surfaces.

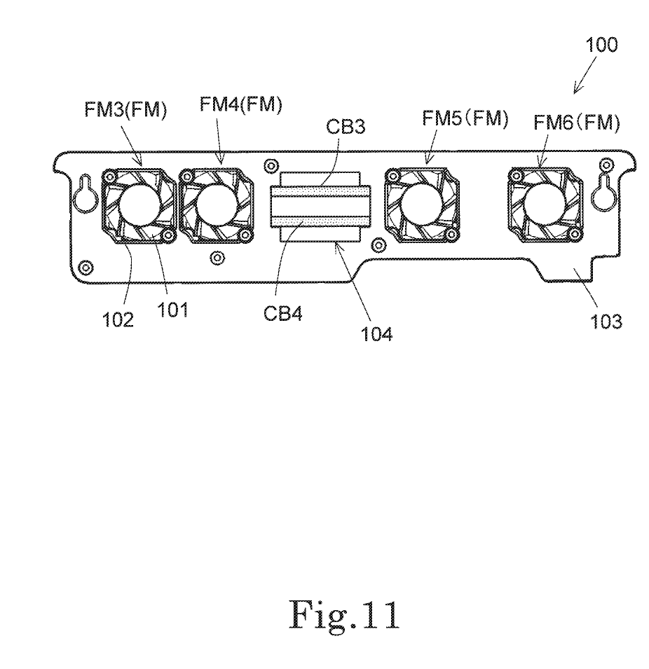

A fan device 100 according to a second embodiment will be described below. Elements of the fan device 100 similar to those of the first embodiment will not be explained unless it is necessary. FIG. 11 is a plan view of the fan device 100 according to the second embodiment, as viewed from above in the axial direction. The fan device 100 includes plural fan motors FM3 through FM6 arranged in the radial direction. Four fan motors are provided in the second embodiment. However, the number of fan motors may be changed appropriately. The fan motors FM3 through FM6, which will be set to be first through fourth fan motors, are aligned in the radial direction. The first through fourth fan motors FM3 through FM6 are axial fan motors which suck air from suction inlets on one side of the axial direction and which evacuate air from evacuate outlets on the other side of the axial direction. In FIG. 11, the central axes of the fan motors FM3 through FM 6 extend in a direction perpendicular to the plane of the drawing. That is, in FIG. 11, the axial direction is a direction perpendicular to the plane of the drawing.

The fan motors FM3 through FM6 each have an impeller 101 and a wall surface 102. The configurations of the fan motors FM3 through FM6 are the same. As in the impeller 5 of the first embodiment, the impeller 101 rotates around the central axis. However, the shape of the impeller 101 is different from that of the impeller 5. As the impeller 101, an existing impeller for an axial fan motor may be used. The wall surface 102 surrounds the impeller 101 outward in the radial direction. The wall surfaces 102 of the fan motors FM3 through FM6 are provided in a casing 103 which houses the fan motors FM3 through FM6 therein. Motor units of the fan motors FM3 through FM6 are similar to the motors 10 in the first embodiment.

As in the first embodiment, the fan device 100 includes a board storage unit 104 for storing plural circuit boards. The board storage unit 104 is provided in the casing 103. The configuration of the board storage unit 104 of the fan device 100 is similar to that of the board storage unit 2 of the first modified example of the first embodiment, though various modifications may be made to the board storage unit 104 as in the first embodiment. In the board storage unit 104, first and second circuit boards CB3 and CB4 are stored.

The board storage unit 104 may be disposed between two fan motors FM adjacent to each other in the radial direction. The board storage unit 104 may alternatively be disposed on one radial-direction side of the fan motor FM positioned at the edge of one side in the radial direction. In the second embodiment, the board storage unit 104 is disposed between the second and third fan motors FM4 and FM5 adjacent to each other in the radial direction. In another embodiment, the board storage unit 104 may be disposed on the left side of the first fan motor FM3 or on the right side of the fourth fan motor FM6. In this case, the wall surfaces 102 may be constituted by the casing 103. In the second embodiment, the fan device 100 including the plural axial fan motors FM extending in the radial direction can be provided.

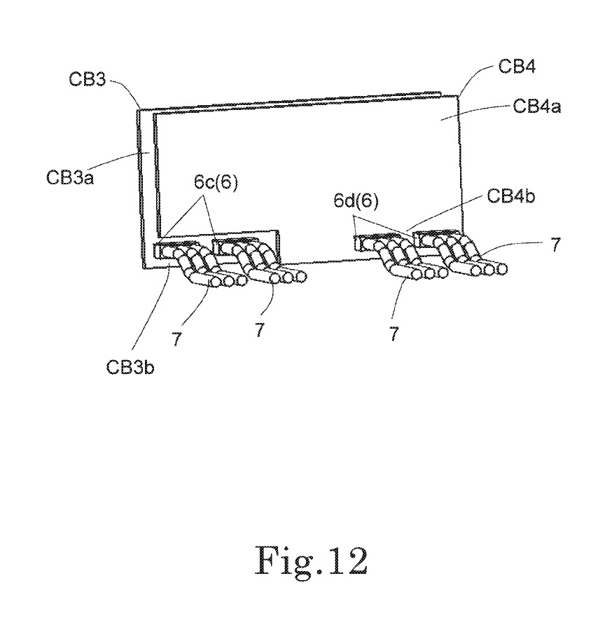

FIG. 12 is a perspective view of the first and second circuit boards CB3 and CB4 of the fan device 100 according to the second embodiment. The first circuit board CB3 includes a control circuit which controls the driving of the first and second fan motors FM3 and FM4. The second circuit board CB4 includes a control circuit which controls the driving of the third and fourth fan motors FM5 and FM6. The first and second circuit boards CB3 and CB4 are connected to each other, as in the first embodiment.

As viewed from the opposing direction of the first and second circuit boards CB3 and CB4, the first circuit board CB3 has a first opposing area CB3a which overlaps the second circuit board CB4 and a first non-opposing area CB3b which does not overlap the second circuit board CB4. As viewed from the same direction, the second circuit board CB4 has a second opposing area CB4a which overlaps the first circuit board CB3 and a second non-opposing area CB4b which does not overlap the first circuit board CB3.

Two first connectors 6c with lead wires 7 are mounted on the first non-opposing area CB3b. A lead wire 7 to be electrically connected to the internal circuit board of the first fan motor FM3 is connected to one of the two first connectors 6c. A lead wire 7 to be electrically connected to the internal circuit board of the second fan motor FM4 is connected to the other first connector 6c. Two second connectors 6d with lead wires 7 are mounted on the second non-opposing area CB4b. A lead wire 7 to be electrically connected to the internal circuit board of the third fan motor FM5 is connected to one of the two second connectors 6d. A lead wire 7 to be electrically connected to the internal circuit board of the fourth fan motor FM6 is connected to the other second connector 6d.

In the second embodiment, after the first and second circuit boards CB3 and CB4 are connected to each other, positioning of the four connectors 6 provided at the ends of lead wires 7 on the first and second circuit boards CB3 and CB4 can be performed from the same side. Then, fixing of the connectors 6 to the circuit boards CB3 and CB4 by soldering can be performed on the side opposite the side on which positioning of the connectors 6 is performed. In the second embodiment, mounting of the connectors 6 with the lead wires 7 on the first and second circuit boards CB3 and CB4 is simple. Hence, the first and second circuit boards CB3 and CB4 can be connected before the connectors 6 are mounted on the first and second circuit boards CB3 and CB4, thereby enhancing the efficiency of the operation.

The present invention may also be applicable to a fan device including a single fan motor. Even in this configuration, in order to decrease the area where circuit boards are disposed, plural circuit boards may be disposed such as to oppose each other, and electronic components may be distributed over the plural circuit boards. The present invention may also be applicable to the configuration in which three or more circuit boards are stored in a board storage unit.

The direction of the circuit boards stored in the board storage units 2 and 104 is not restricted to the direction described in the first and second embodiments. The circuit boards may be stored in a different direction. For example, in the configuration in FIG. 1, the circuit boards CB1 and CB2 may be stored in the board storage unit 2 such that the board surfaces are parallel with a direction perpendicular to the horizontal direction. The circuit boards CB1 and CB2 may alternatively be stored in the board storage unit 2 such that the board surfaces are parallel with a direction perpendicular to the axial direction. In this case, the board storage unit 2 is opened in the front-back direction.

Features of the above-described preferred embodiments and the modifications thereof may be combined appropriately as long as no conflict arises.

The present invention is applicable to a fan device, for example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A fan device comprising:
a fan motor; and
a board storage unit for storing a plurality of circuit boards therein,
the fan motor including
an impeller that rotates around a central axis, and
a wall surface that surrounds the impeller outward in a radial direction,
wherein
the board storage unit is disposed outward from the wall surface in the radial direction,
the plurality of circuit boards include first and second circuit boards to be connected to each other such that the first and second circuit boards oppose each other,
as viewed from a direction in which the first and second circuit boards oppose each other,
the first circuit board has a first opposing area which overlaps the second circuit board and a first non-opposing area which does not overlap the second circuit board, and
the second circuit board has a second opposing area which overlaps the first circuit board and a second non-opposing area which does not overlap the first circuit board, and
an electronic component or a lead wire is disposed in each of the first and second non-opposing areas.

2. The fan device according to claim 1, wherein
as viewed from a direction in which the first and second circuit boards oppose each other,
at least one of a first boundary between the first opposing area and the first non-opposing area of the first circuit board and a second boundary between the second opposing area and the second non-opposing area of the second circuit board opposes part of a periphery of the other one of the first and second circuit boards.

3. The fan device according to claim 1, wherein:
a first connector, which serves as the electronic component, is disposed in the first non-opposing area;
a second connector, which serves as the electronic component, is disposed in the second non-opposing area;
the first connector is disposed on a side of the first circuit board which opposes the second circuit board; and
the second connector is disposed on a side of the second circuit board which does not oppose the first circuit board.

4. The fan device according to claim 1, wherein the fan device comprises a plurality of the fan motors.

5. The fan device according to claim 4, wherein:
the plurality of fan motors are centrifugal fan motors which suck air from suction inlets disposed on one side of an axial direction and which evacuate air from evacuate outlets on an outward side of the radial direction;
the plurality of fan motors include first and second fan motors arranged in the radial direction; and
the board storage unit is disposed between a first evacuate outlet of the first fan motor and a second evaluate outlet of the second fan motor.

6. The fan device according to claim 4, wherein:
the plurality of fan motors are axial fan motors which suck air from suction inlets disposed on one side of an axial direction and which evacuate air from evacuate outlets on the other side of the axial direction;
the plurality of fan motors are arranged in the radial direction; and
the board storage unit is disposed between two fan motors adjacent to each other in the radial direction among the plurality of fan motors or is disposed on one radial-direction side of the fan motor positioned at an edge of one side in the radial direction.

7. The fan device according to claim 1, wherein:
the board storage unit is opened in one direction;
the first and second circuit boards are disposed in parallel with one direction;
an inner surface of the board storage unit has at least one rib extending in one direction; and
one of board surfaces of the first circuit board or the second circuit board contacts the rib.

8. The fan device according to claim 1, wherein:
the board storage unit is opened in one direction;
the first and second circuit boards are disposed in parallel with one direction;
an inner surface of the board storage unit has at least two ribs extending in one direction; and
the first circuit board or the second circuit board is disposed between two of the at least two ribs.

9. The fan device according to claim 1, wherein:
the board storage unit is opened in one direction;
the first and second circuit boards are disposed in parallel with one direction;
the board storage unit has at least one groove which is depressed outward from an inner surface of the board storage unit and which extends in one direction; and
an inner surface of the groove contacts at least one of board surfaces of the first circuit board and at least one of board surfaces of the second circuit board.

10. The fan device according to claim 1, wherein:
the first and second circuit boards are congruent with each other; and
if one of the first and second circuit boards connected to each other is flipped horizontally, the shape of the horizontally flipped circuit board is identical to the shape of the other one of the first and second circuit boards.
